(19) United States
(12) Patent Application Publication
(10) Pub. No.: US 2014/0145284 A1
(43) Pub. Date: May 29, 2014

(54) PHOTODIODE FOR AN IMAGE SENSOR AND METHOD OF FABRICATING THE SAME

(71) Applicant: Shanghai Huali Microelectronics Corporation, Shanghai (CN)

(72) Inventors: Chunsheng ZHENG, Shanghai (CN); Wenguang ZHANG, Shanghai (CN); Yuwen CHEN, Shanghai (CN)

(73) Assignee: Shanghai Huali Microelectronics Corporation, Shanghai (CN)

(21) Appl. No.: 14/055,394

(22) Filed: Oct. 16, 2013

(30) Foreign Application Priority Data
Nov. 28, 2012 (CN) 201210496217.7

(51) Int. Cl. H01L 31/0236; H01L 31/18

(52) U.S. Cl. CPC H01L 31/02363; H01L 31/18
USPC 257/432; 438/71

(57) ABSTRACT

A photodiode for an image sensor and a method of fabricating the photodiode are disclosed. The photodiode includes a substrate having a surface defined as a light-incident surface of the photodiode, wherein a plurality of convex structures are provided on the light-incident surface of the photodiode, namely, a non-planar light-incident surface which is capable of reducing the light reflection and hence improving the ability of the photodiode to capture incident light, thereby enabling an image sensor that incorporates the photodiode to have a higher fill factor and a better performance.

### CROSS-REFERENCES TO RELATED APPLICATIONS

This application claims the priority of Chinese patent application number 201210496217.7, filed on Nov. 28, 2012, the entire contents of which are incorporated herein by reference.

### TECHNICAL FIELD

The present invention relates, in general, to the fabrication of integrated circuits, and in particular, to a photodiode for use in an image sensor and method of fabricating the same.

### BACKGROUND

Advent of the integrated circuit technology has brought tremendous changes to the fields of computers, control systems, communications, imaging, etc. In the field of imaging, image sensors are a key component for digital cameras. Typically, according to the type of electronic device adopted in an image sensor, image sensors are classified into two groups, charge coupled device (CCD) image sensors and complementary metal-oxide semiconductor (CMOS) image sensors, and the CMOS image sensors have captured a large portion of the market share of the applications in relation with CCD image sensors.

Chinese Patent Publication No. CN101986432A discloses the invention of a CMOS image sensor as shown in FIG. 1. The CMOS image sensor includes a lens 11, a plurality of microlenses 13, a plurality of color filters 15, and a plurality of light-sensitive elements 17. The pluralities of microlenses 13, color filter units 15 and light-sensitive elements 17 are aligned with one another. When light beams are incident on the CMOS image sensor, the beams will sequentially pass through the lens 11, the microlenses 13 and the color filter units 15 and are thereafter distributed on the light-sensitive elements 17.

Chinese Patent Publication No. CN2681352Y discloses the invention of another type of an image sensor as shown in FIG. 2. The image sensor mainly includes a protective cap layer 1, a microlens array 3, a plurality of lenses 4, a color filter array 5, a plurality of light-receiving units 7 and a signal processing printed circuit board (PCB) 9 in this order from the top downwards. Wherein the microlens array 3 is a two-dimensional array consisting of a plurality of microlenses.

In these and other prior art image sensors, each pixel typically includes a light-sensitive element (e.g., a photoelectric conversion assembly) which converts the received light into an electric signal. For example, each pixel of a prior art CMOS image sensor illustrated in FIG. 3 includes a photodiode PD for photoelectric conversion and MOS transistors for electrical signal manipulation and switching. As illustrated in FIG. 3, a P-type substrate and an N+ region of the pixel may serve as first and second electrodes of the photodiode PD, respectively, and each of the MOS transistors may operate in accordance with a signal applied to a gate of it between two adjacent N+ regions. The gate may include a gate dielectric layer GD stacked above the substrate and a gate conductive film GC stacked above the gate dielectric layer GD. The photodiode PD may have a light-receiving area for light 2 incident on the P-type substrate larger than a light-receiving area for light 1 incident on the N+ region. For example, in the case that the illustrated CMOS image sensor is a back-side-illuminated image sensor, it can receive light incident on the P-type substrate. However, as the P-type substrate (typically a P-type silicon substrate) assumes a planar surface which has a high degree of light reflection, the image sensor has a relatively low fill factor. Although the microlenses (or the microlens array) adopted in the above-described prior art devices can intensify the incident light to a certain extent, the requirement for a sufficient incident light intensity could not be thereby satisfied yet. Thus, there is a need for a photodiode capable of improving the fill factor for an image sensor and such an image sensor using the photodiode.

### SUMMARY OF THE INVENTION

An objective of the present invention is to provide a photodiode for an image sensor, which has a non-planar light-incident surface capable of reducing light reflection and hence improving the ability of the photodiode to capture incident light, thereby enabling an image sensor employing the photodiode to have a higher fill factor and a better performance. Another objective of the present invention is to provide a method of fabricating the photodiode.

The above objectives are attained by a photodiode for an image sensor, which includes a substrate having a surface defined as a light-incident surface of the photodiode, wherein a plurality of convex structures are provided on the light-incident surface of the photodiode.

Optionally, each of the plurality of convex structures may be a trigonal pyramid, a tetragonal pyramid, a hexagonal pyramid, an octagonal pyramid, or a circular cone.

Optionally, each of the plurality of convex structures may include: a bottom face having a shape of a regular polygon of n sides; and n inclined side faces each having an identical size and having a shape of an isosceles triangle, wherein each of the n inclined side faces forms an angle of between 0 degree and 90 degrees, and preferably, 45 degrees, with the bottom face and n is a natural number of greater than or equal to 3. Additionally, every two adjacent ones of the plurality of convex structures may have a common side.

Optionally, the photodiode for an image sensor may further include a P-well in the substrate and an N+ region in the P-well.

Alternatively, the photodiode for an image sensor may further include an N+ region in the substrate.

The above objectives are also attained by a method of fabricating a photodiode for an image sensor, which includes the steps of: providing a substrate having a surface defined as a light-incident surface of the photodiode; and forming a plurality of convex structures on the light-incident surface of the photodiode.

Optionally, the step of forming the plurality of convex structures may include the step of immersing the light-incident surface of the photodiode into an alkaline solution with a surface of the substrate opposite to the light-incident surface out of the alkaline solution, thereby eroding the light-incident surface of the photodiode with the alkaline, solution to form the plurality of convex structures thereon.

Optionally, the step of forming the plurality of convex structures may farther include the steps of: rinsing the substrate for a first time; performing a dehydration and metal ion removal process on the rinsed substrate; rinsing the substrate for a second time; and air drying the substrate.

Alternatively, the step of forming the plurality of convex structures may include the steps of: forming a plurality of photoresist bumps on the light-incident surface of the photodiode; baking the photoresist bumps; and performing an inductive coupled plasma dry etching process using the baked photoresist bumps as masks until the baked photoresist bumps have been totally etched away, thereby forming the plurality of convex structures on the light-incident surface of the photodiode.

Optionally, the method may further include the steps of: forming a P-well in the substrate; and forming an N+ region in the P-well.

Alternatively, the method may further include the step of forming an N+ region in the substrate.

Compared to the prior art, the photodiode of the present invention advantageously includes a light-incident surface with a plurality of convex structures, namely, a non-planar light-incident surface which is capable of reducing light reflection, thereby improving the ability of the photodiode to capture incident light. This can enable an image sensor employing the photodiode to have a higher fill factor and hence a better performance.

### BRIEF DESCRIPTION OF THE DRAWINGS

FIG. 1 depicts a cross-sectional view of a prior art image sensor.

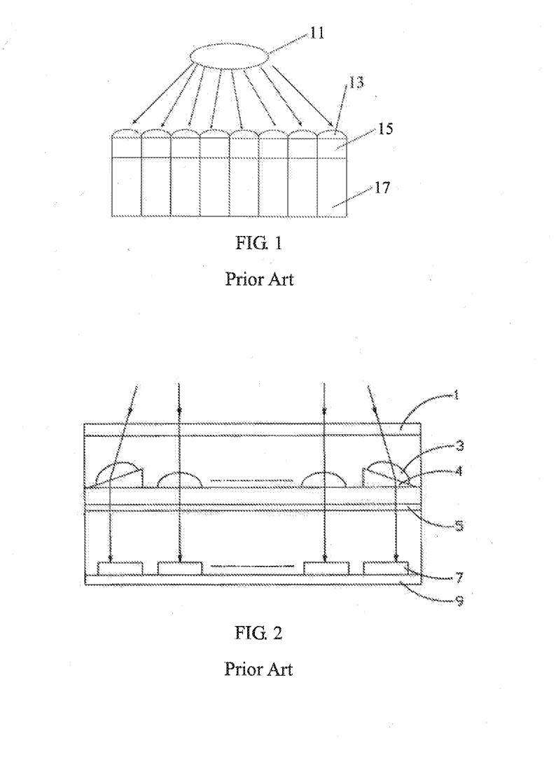

FIG. 2 depicts a cross-sectional view of another prior art image sensor.

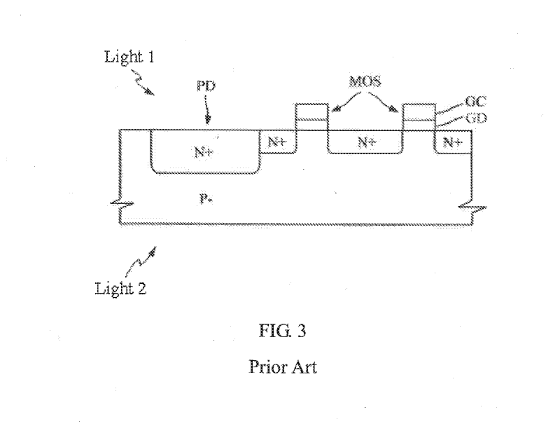

FIG. 3 depicts a cross-sectional view of a pixel of a prior art image sensor.

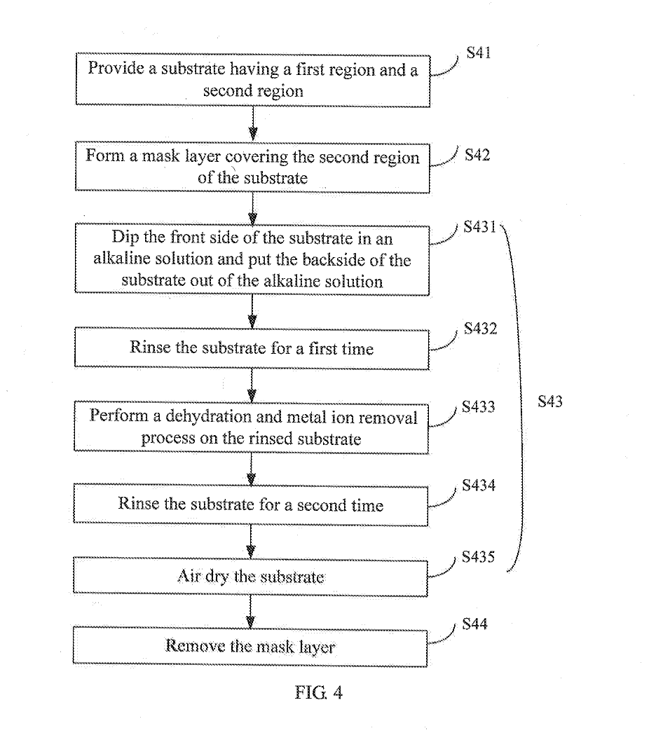

FIG. 4 depicts a flowchart graphically illustrating a method of fabricating a photodiode for an image sensor in accordance with Embodiment 1 of the present invention.

FIGS. 5A to 5D are cross-sectional views depicting the sequence of process steps to fabricate the photodiode for an image sensor by the method in accordance with Embodiment 1 of the present invention.

FIG. 6 depicts a flowchart graphically illustrating a method of fabricating a photodiode for an image sensor in accordance with Embodiment 2 of the present invention.

FIGS. 7A to 7F are cross-sectional views depicting the sequence of process steps to fabricate the photodiode for an image sensor by the method in accordance with Embodiment 2 of the present invention.

FIG. 8 is a cross-sectional view illustrating a plurality of convex structures formed on a light-incident surface of a photodiode constructed in accordance with Embodiment 2 of the present invention.

### DETAILED DESCRIPTION

A core concept of the present invention is that forming a plurality of convex structures on a light-incident surface of a photodiode is able to reduce the light reflection and hence improve the ability of the photodiode to capture the incident light, thereby enabling an image sensor that incorporates the photodiode to have a higher fill factor and a better performance, and is also able to extend the length for light to travel through the photodiode, thereby improving the quantum efficiency thereof, in particular in the range of red light with a relatively long wavelength.

To further describe the present invention, reference is made to the following detailed description on exemplary embodiments, taken in conjunction with the accompanying drawings. The features and advantages of the invention will become better understood by reference to the following detailed description and appended claims. Note that all the accompanying drawings are presented in a very simple form and not drawn precisely to scale. They are provided solely to facilitate the description of the exemplary embodiments of the invention in a convenient and clear way.

### Embodiment 1

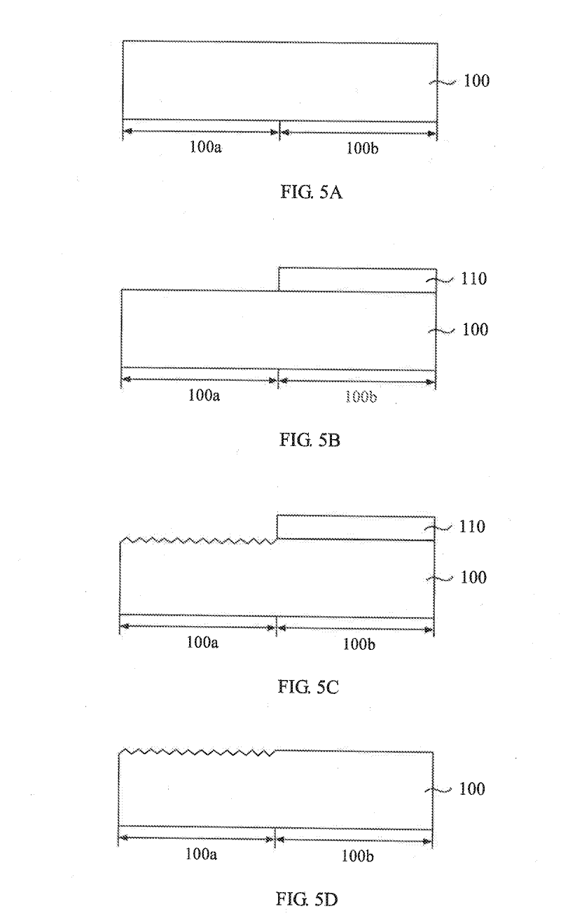

FIG. 4 depicts a flowchart graphically illustrating a method of fabricating a photodiode for an image sensor in accordance with this embodiment. The method includes the following steps S41 to S44.

In the step S41, a substrate having a first region and a second region is provided.

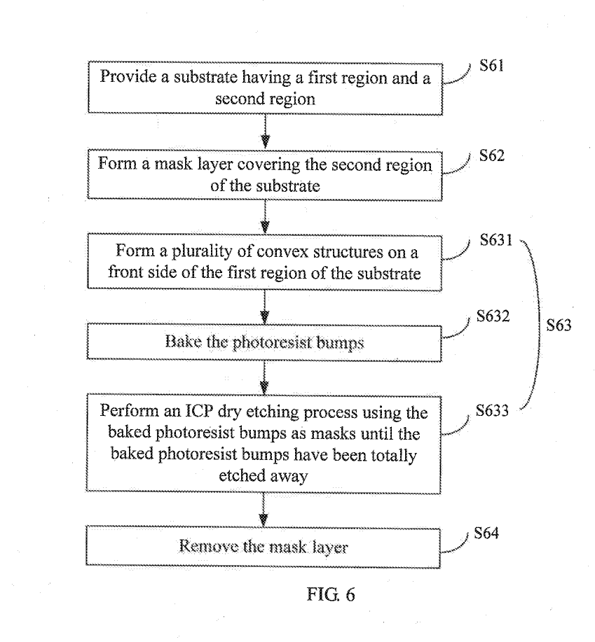

Specifically, referring to FIG. 5A, a substrate 100 is provided which has a first region 100a for fabricating a photodiode and a second region 100b for fabricating MOS transistors.

In the step S42, a mask layer is formed, covering the second region of the substrate.

Specifically, referring to FIG SB, as the first region 100a of the substrate 100 is to fabricate the photodiode, the convex structures are to be formed thereon, in order to prevent the rest of the substrate 100 from being damaged in an etching process performed in a subsequent step, the surface of the rest of the substrate 100 (i.e., second region 100b) is covered with a mask layer 110 such as, for example, a silicon nitride layer, which is resistant to a chemical reagent used to etch the substrate 100 in the etching process.

In the step S43, a plurality of convex structures are formed in the first region of the substrate.

Specifically, referring to FIG. 5C, a wet etching process, i.e., a chemical etching approach, may be employed to etch the substrate 100 to lead its originally planar surface to a non-planar surface with convexes and concaves formed thereon so as to extend the length for light to travel through the surface and thereby improve the light absorption of the photodiode being fabricated thereon. In this embodiment, all the convex structures are formed only on a front side of the substrate 100, by immersing the front side of the substrate 100 in a solution of a chemical reagent with a backside of the substrate 100 out of the solution. Specifically, this process may be roller controlled by a wet-etching apparatus and a certain quantity of sulfuric acid or ethylene glycol may be added into the solution to increase its density and viscosity, thereby allowing the substrate 100 to float on the solution with its front side dipped therein and the backside left out thereof. As the substrate of most photodiodes is generally monocrystalline silicon, the chemical reagent used in the wet etching process may preferably include a reagent that is able to etch the monocrystalline silicon. In this embodiment, forming the convex structures on the substrate by wet etching may further include the following steps S431 to S434.

In the step S431, the front side of the substrate is dipped in an alkaline solution held in a wet-etching apparatus, and the backside of the substrate is kept out of the alkaline solution.

It is a matter of course that the step S431 may be preceded by performing ultrasonic cleaning and a pre-treatment on the substrate.

Preferably, in this step, the substrate is disposed in the alkaline solution held in a wet-etching apparatus and roller controlled to float on the alkaline solution with its front side dipped therein and the backside left out thereof. The alkaline solution may be a mixture of sodium silicate, sodium hydroxide, isopropanol, deionized water and ethylene glycol mixed in a volume ratio of 1:3.5:6:180:40, wherein ethylene glycol is added to increase the density and viscosity of the solution so as to facilitate the substrate to float thereon. Temperature of the alkaline solution may be controlled between 70° C. and 80° C., and the substrate may be processed in the alkaline solution for 10 minutes to 45 minutes.

In the step S432, the substrate is rinsed for a first time.

Specifically, after the substrate floating on the alkaline solution is taken out, it may be preferably put and rinsed in warm water with a temperature of 35° C. to 55° C. contained in an insulated tank.

In the step S433, a dehydration and metal ion removal process is performed on the rinsed substrate.

Specifically, the rinsed substrate may be preferably immersed in a hydrofluoric acid solution or a hydrochloric acid solution to have moisture and metal ions contained therein removed.

In the step S434, the substrate is rinsed for a second time.

Specifically, the substrate may be preferably once again put and rinsed in warm water with a temperature of 35° C. to 55° C. contained in an insulated tank.

In the step S435, the substrate is air dried.

Specifically, the substrate may be preferably air dried thoroughly with compressed air or nitrogen.

In the step S44 of the method in this embodiment, the mask layer is removed.

Specifically, referring to FIG. 5D, the mask layer 110 is removed after the convex structures have been formed in the first region 100a of the substrate 100 by wet etching. As such, after the steps S41 to S44, the region of substrate 100 that was not covered by the mask layer 110 has a non-planar surface of pyramidal shape.

Subsequently, regular processes for forming a photodiode are to be performed, including, for example, forming a P-well in the first region of the P-type substrate and an N+ region in the P-well, or alternatively, only forming an N+ region in the P-type substrate (in this case, the P-type substrate serves as a first electrode of the photodiode, and the N+ region as a second electrode). As all of these processes are well known to persons of ordinary skill in the art, further description of them is not necessary.

As discussed above, advantageously, the convex structures formed on the surface of the substrate is capable of effectively reducing the light reflection, and designing this surface as a light-incident surface of the photodiode can therefore improve the ability of the photodiode to capture incident light. This can enable an image sensor that incorporates the photodiode to have a higher fill factor and hence a better performance.

### Embodiment 2

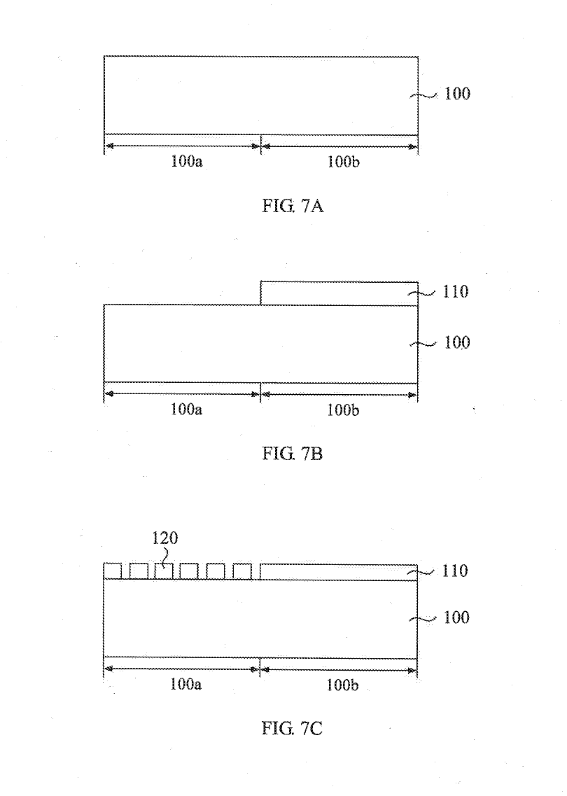

FIG. 6 depicts a flowchart graphically illustrating a method of fabricating a photodiode for an image sensor in accordance with this embodiment. The method includes the following steps S61 to S64.

In the step S61, a substrate having a first region and a second region is provided.

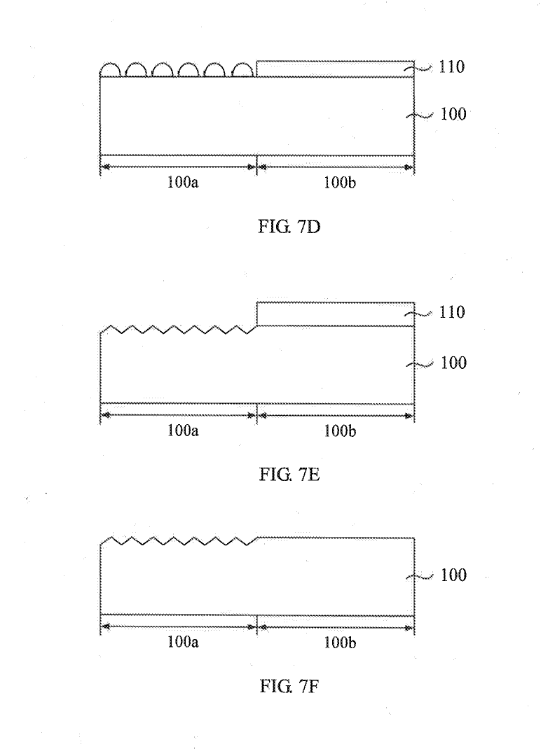

Specifically, referring to FIG. 7A, a substrate 100 is provided which has a first region 100a for fabricating a photodiode and a second region 100b for fabricating MOS transistors.

In the step S62, a mask layer is formed, covering the second region of the substrate.

Specifically, referring to FIG. 7B, as the first region 100a of the substrate 100 is the region used to fabricate the photodiode, the convex structures are to be formed thereon, in order to prevent the rest of the substrate 100 from being damaged in an etching process performed in a subsequent step, the surface of the rest of the substrate 100 (i.e., second region 100b) is covered with a mask layer 110 such as, for example, a silicon nitride layer, which is resistant to a chemical reagent used to etch the substrate 100 in the etching process.

In the step S63, a plurality of convex structures are formed in the first region of the substrate.

Specifically, a plurality of convex structures may be formed in the first region 100a of the substrate 100 using a dry etching process include the following steps S631 to S633.

In the step S631, a plurality of photoresist bumps are formed on a front side of the first region of the substrate.

Specifically, referring to FIG. 7C, a plurality of photoresist bumps 120 may be formed on the first region 100a of the substrate 100 by photoresist application, exposure and development.

In the step S632, the photoresist bumps are baked.

Specifically, referring to FIG. 7D, the photoresist bumps 120 may be baked at a preset temperature (e.g., between 120° C. and 250° C.) that is higher than the glass transition temperature of the photoresist, and their upper portions are thereby rounded or tapered due to surface tension. In the case of cylindrical photoresist bumps, each of the photoresist bumps resembles in shape a spherical cap after backed. Otherwise, in the case of photoresist bumps each having a triangular, quadrangular, or another polygonal top-view cross section, upper portions of the photoresist bumps are tapered (i.e., larger at the bottom and smaller at the top) after backed.

In the step S633, an inductive coupled plasma (ICP) dry etching process is performed using the baked photoresist bumps as masks until the baked photoresist bumps have been totally etched away, thereby forming the plurality of convex structures on the front side of the first region of the substrate which thereafter serves as a light-incident surface of the photodiode being fabricated.

Specifically, referring to FIG. 7E, an ICP dry etching process is performed once using the baked photoresist bumps as masks until the baked photoresist bumps have been totally etched away to form the plurality of convex structures on the surface of the substrate. In the ICP dry etching process, in order to form the plurality of pyramidal convex structures, an etching rate ratio of the substrate to the baked photoresist bumps may be controlled in a range of 1 to 2 by means of, but not limited to, setting the plate power applied to the substrate higher than the coil power. Alternatively, the etching rate ratio of the substrate to the baked photoresist bumps may also be controlled in the aforementioned range by manipulating other etching parameters.

In the step S64 of the method according to this embodiment, the mask layer is removed.

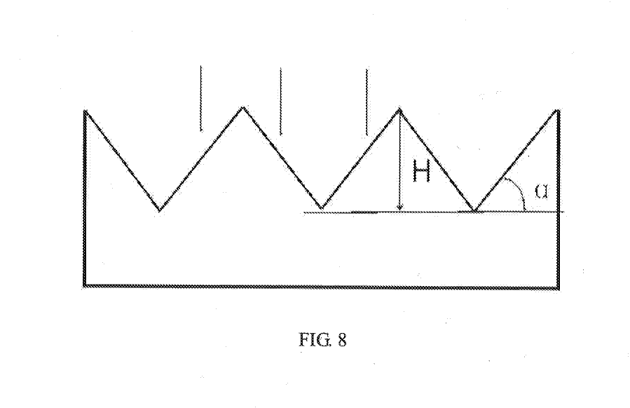

Specifically, referring to FIG. 7F, mask layer 110 is removed after the convex structures have been formed in the first region 100a of the substrate 100 by dry etching. As such, a plurality of pyramidal convex structures are formed in the region of the substrate 100 that was not covered by the mask layer after the steps S61 to S64. Each convex structure may be a trigonal pyramid, a tetragonal pyramid, a hexagonal pyramid, an octagonal pyramid, or a circular cone. As illustrated in FIG. 8, each convex structure may include: a bottom face having a shape of a regular polygon of n sides; and n inclined side faces each having an identical size and having a shape of an isosceles triangle, wherein n is a natural number greater than or equal to 3. Perpendicular height H of each convex structure from the apex to the bottom face should be smaller than a thickness of the substrate, and may preferably be about 10 nm. Every two adjacent convex structures may have a common side. In each convex structure, each inclined side face may form an angle α of 0 degree to 90 degrees with the bottom face, and preferably the angle α is 45 degrees. Ability of the photodiode to capture light increases with the angle α increasing from 0 degree to 90 degrees.

Subsequently, processes for forming a regular photodiode may be performed to complete the photodiode being fabricated, including, for example, forming a P-well in first region of the P-type substrate and an N+ region in the P-well, or alternatively, only forming an N+ region in the P-type substrate (in this case, the P-type substrate serves as a first electrode of the photodiode, and the N+ region as a second electrode). As all of these processes are well known to persons of ordinary skill in the art, further description of them is not necessary.

As discussed above, advantageously, the convex structures formed on the surface of the substrate is capable of effectively reducing the light reflection, and designing this surface as a light-receiving surface of the photodiode can therefore improve the ability of the photodiode to capture incident light. This can enable an image sensor that incorporates the photodiode to have a higher fill factor and hence a better performance.

### Embodiment 3

This embodiment of the present invention provides an image sensor incorporating a photodiode made according to one of the methods described above. The image sensor includes a substrate having a surface defined as a light-incident surface of the photodiode, wherein a plurality of convex structures are provided on the light-incident surface of the photodiode. Advantageously, the plurality of convex structures on the light-incident surface of the photodiode are capable of reducing the light reflection and hence improving the ability of the photodiode to capture incident light, thereby enabling the image sensor to have a higher fill factor and hence a better performance.

The image sensor may either be a front-side-illuminated (FSI) image sensor or a BSI image sensor. As this invention relates only to the photodiode, other components of the image sensor that are known to those skilled in the art are not further described herein.

It is apparent that those skilled in the art can make various modifications and variations to the present invention without departing from the scope of the invention. Accordingly, it is intended that the present invention embraces all such modifications and variations as fall within the scope of the appended claims and equivalents thereof.

What is claimed is:

1. A photodiode for an image sensor, comprising:
a substrate having a surface defined as a light-incident surface of the photodiode, wherein a plurality of convex structures are provided on the light-incident surface of the photodiode.

2. The photodiode for an image sensor of claim 1, wherein each of the plurality of convex structures is a trigonal pyramid, a tetragonal pyramid, a hexagonal pyramid, an octagonal pyramid, or a circular cone.

3. The photodiode for an image sensor of claim 2, wherein each of the plurality of convex structures includes:
a bottom face having a shape of a regular polygon of n sides; and
n inclined side faces each having an identical size and having a shape of an isosceles triangle,
wherein each of the n inclined side faces forms an angle of between 0 degree and 90 degrees with the bottom face and n is a natural number of greater than or equal to 3, and wherein every two adjacent ones of the plurality of convex structures have a common side.

4. The photodiode for an image sensor of claim 3, wherein, in each of the plurality of convex structures, each of the n inclined side faces forms an angle of 45 degrees with the bottom face.

5. The photodiode for an image sensor of claim 1, further comprising a P-well in the substrate and an N+ region in the P-well.

6. The photodiode for an image sensor of claim 1, further comprising an N+ region in the substrate.

7. A method of fabricating a photodiode for an image sensor, comprising the steps of:
providing a substrate having a surface defined as a light-incident surface of the photodiode; and
forming a plurality of convex structures on the light-incident surface of the photodiode.

8. The method of claim 7, wherein the step of forming the plurality of convex structures includes the step of immersing the light-incident surface of the photodiode into an alkaline solution with a surface of the substrate opposite to the light-incident surface out of the alkaline solution, thereby eroding the light-incident surface of the photodiode with the alkaline solution to form the plurality of convex structures thereon.

9. The method of claim 8, wherein the step of forming the plurality of convex structures further includes the steps of:
rinsing the substrate for a first time;
performing a dehydration and metal ion removal process on the rinsed substrate;
rinsing the substrate for a second time; and
air drying the substrate.

10. The method of claim 7, wherein the step of forming the plurality of convex structures includes the steps of:
forming a plurality of photoresist bumps on the light-incident surface of the photodiode;
baking the photoresist bumps; and
performing an inductive coupled plasma dry etching process using the baked photoresist bumps as masks until the baked photoresist bumps have been totally etched away, thereby forming the plurality of convex structures on the light-incident surface of the photodiode.

11. The method of claim 7, further comprising the steps of:
forming a P-well in the substrate; and
forming an N+ region in the P-well.

12. The method of claim 7, further comprising the step of:
forming an N+ region in the substrate.
